(19) United States
(12) Patent Application Publication
(10) Pub. No.: US 2026/0255956 A1
(43) Pub. Date: Aug. 27, 2026

(54) THERMALLY CONDUCTIVE STRUCTURE FOR HEAT DISSIPATION AT AN INTEGRATED CIRCUIT DIE

(71) Applicant: STMicroelectronics International N.V., Geneva (CH)

(72) Inventors: Benedetta FANELLI, Monza E Brianza (IT); Giuseppe Livio GOBBATO, Milan (IT)

(21) Appl. No.: 19/064,976

(22) Filed: Feb. 27, 2025

(51) Int. Cl. H01L 23/00; H01L 23/367; H01L 23/373; H01L 23/495

(52) U.S. Cl. CPC H10W 40/22; H10W 70/461; H10W 40/255; H10W 72/621; H10W 72/634; H10W 72/871; H10W 72/884; H10W 72/886; H10W 90/736; H10W 90/754; H10W 90/766

(57) ABSTRACT

An example thermally conductive structure, and an example lead-frame package comprising a thermally conductive structure for dissipating heat at an integrated circuit die in a lead-frame package are provided. The example lead-frame package comprising a frame portion, an integrated circuit die, and a thermally conductive structure. The integrated circuit die being positioned on the frame portion and comprising an integrated circuit die width. The thermally conductive structure comprising an anchor portion and a bridge portion. The anchor portion attached to a top frame surface of the frame portion. The bridge portion comprising a uniform bridge portion width, wherein the uniform bridge portion width is less than the integrated circuit die width, and wherein the bridge portion is in thermal contact with the integrated circuit die.

### TECHNOLOGICAL FIELD

Embodiments of the present disclosure relate generally to a thermally conductive structure to provide heat dissipation at an integrated circuit (IC) die, and more particularly, to a thermally conductive structure to provide heat dissipation at an IC die in a lead-frame package.

### BACKGROUND

Many electronic systems utilize printed circuit boards (PCBs) to support and connect the various electrical components of the electronic system. For example, a PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various integrated circuits (ICs). One example structure for connecting an IC to a PCB is a lead-frame package.

Applicant has identified many technical challenges and difficulties associated with heat dissipation at an IC on a lead-frame package. Through applied effort, ingenuity, and innovation, Applicant has solved problems related to heat dissipation in a lead-frame package by developing solutions embodied in the present disclosure, which are described in detail below.

### BRIEF SUMMARY

Various embodiments are directed to an example thermally conductive structure, an example lead-frame package comprising a thermally conductive structure for dissipating heat at an integrated circuit die in a lead-frame package.

An example lead-frame package is provided. The example lead-frame package comprising a frame portion, an integrated circuit die, and a thermally conductive structure. The integrated circuit die being positioned on the frame portion and comprising an integrated circuit die width. The thermally conductive structure comprising an anchor portion and a bridge portion. The anchor portion attached to a top frame surface of the frame portion. The bridge portion comprising a uniform bridge portion width, wherein the uniform bridge portion width is less than the integrated circuit die width, and wherein the bridge portion is in thermal contact with the integrated circuit die.

In some embodiments, the integrated circuit die comprising a first set of wire bond pads on a first side of a top IC surface, and a second set of wire bond pads on a second side of the top IC surface.

In some embodiments, the bridge portion of the thermally conductive structure is attached to the top IC surface between the first set of wire bond pads and the second set of wire bond pads.

In some embodiments, the thermally conductive structure is attached to the integrated circuit die with an IC attach material, wherein the IC attach material is a thermally conductive but electrically insulating material.

In some embodiments, a molding material defines a top package surface of the lead-frame package, wherein an elevated portion of the bridge portion of the thermally conductive structure is exposed at the top package surface.

In some embodiments, a structure height associated with the thermally conductive structure is uniform along a structure length of the thermally conductive structure.

In some embodiments, the thermally conductive structure further comprising a first end of the bridge portion, wherein a first cross member is attached to the first end of the bridge portion, and the first cross member is attached to the frame portion of the lead-frame package.

In some embodiments, the thermally conductive structure further comprising a second end of the bridge portion, wherein a second cross member is attached to the second end of the bridge portion, and the second cross member is attached to the frame portion of the lead-frame package.

In some embodiments, the bridge portion comprises a first sub portion and a second sub portion. The first sub portion comprising a first height, wherein the first sub portion is in thermal contact with the integrated circuit die; and the second sub portion comprising a second height, wherein the second height is less than the first height.

In some embodiments, the first height associated with the first sub portion of the bridge portion is greater than an anchor portion height associated with the anchor portion.

A thermally conductive structure configured to dissipate heat at an integrated circuit die is also provided. In some embodiments, the thermally conductive structure comprising an anchor portion, and a bridge portion. The anchor portion is attached to a top frame surface of a frame portion of a lead-frame package. The bridge portion comprising a uniform bridge portion width, wherein the uniform bridge portion width is less than an integrated circuit die width associated with the integrated circuit die of the lead-frame package. The bridge portion is in thermal contact with the integrated circuit die.

In some embodiments, the integrated circuit die comprises a top IC surface, wherein the bridge portion of the thermally conductive structure is attached to the top IC surface between a first set of wire bond pads and a second set of wire bond pads.

In some embodiments, the thermally conductive structure is attached to the integrated circuit die with an IC attach material, wherein the IC attach material is a thermally conductive but electrically insulating material.

In some embodiments, an elevated portion of the bridge portion is exposed at a top package surface of the lead-frame package.

In some embodiments, the thermally conductive structure further comprising a structure height, wherein the structure height is uniform along a structure length of the thermally conductive structure.

In some embodiments, the thermally conductive structure comprises a first end of the bridge portion. A first cross member is attached to the first end of the bridge portion, and the first cross member is attached to the frame portion of the lead-frame package.

In some embodiments, the thermally conductive structure comprises a second end of the bridge portion. A second cross member is attached to the second end of the bridge portion, and the second cross member is attached to the frame portion of the lead-frame package.

In some embodiments, the bridge portion comprises a first sub portion and a second sub portion. The first sub portion comprising a first height, wherein the first sub portion is in thermal contact with the integrated circuit die. The second sub portion comprising a second height, wherein the second height is less than the first height.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates a lateral section view of a standard lead-frame package comprising an integrated circuit (IC) die.

FIG. 2 depicts a perspective view of a thermally conductive structure in thermal contact with an IC die in a lead-frame package in accordance with an example embodiment of the present disclosure.

FIG. 3 depicts an overhead view of an example thermally conductive structure in thermal contact with an IC die in a lead-frame package in accordance with an example embodiment of the present disclosure.

FIG. 4 depicts a lateral section view of an example thermally conductive structure in thermal contact with an IC die in a lead-frame package in accordance with an example embodiment of the present disclosure.

FIG. 5 depicts a lateral view of an example thermally conductive structure in thermal contact with an IC die in a lead-frame package comprising a molding material in accordance with an example embodiment of the present disclosure.

FIG. 6 depicts an overhead view of a plurality of thermally conductive structures within an electronic system in accordance with an example embodiment of the present disclosure.

FIG. 7 depicts a perspective view of an example embodiment of a thermally conductive structure comprising a uniform structure height in accordance with an example embodiment of the present disclosure.

### DETAILED DESCRIPTION

Example embodiments will be described more fully hereinafter with reference to the accompanying drawings, in which some, but not all embodiments of the inventions of the disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

Various example embodiments address technical problems associated with heat dissipation from an integrated circuit in a lead-frame package. As understood by those of skill in the field to which the present disclosure pertains, there are numerous example scenarios in which improved heat dissipation at an integrated circuit in a lead-frame package may be beneficial.

For example, many electronic systems utilize printed circuit boards (PCBs) to support and connect the various electrical components of the electronic system. For example, a PCB may include a rigid structure with a plurality of mount regions configured to receive various electrical components. The PCB may further include conductive traces or paths to enable electrical connections between the various electrical components. A PCB may commonly receive surface-mounted and/or socketed electrical components, including various integrated circuits (ICs).

One example structure for connecting an IC to a PCB is a lead-frame package. A lead-frame package is a surface-mount technology providing structural support for an IC, protection from environmental factors, and an electrical connection between the PCB and the IC without through holes. Conductive surfaces on the bottom surface of the lead-frame package are coupled with conductive surfaces on the surface of the PCB. The lead-frame package protects the electrical components and electrical connections of the IC from environmental factors ensuring reliability of the electrical system even in extreme conditions. Example lead-frame packages may include quad-flat lead-frame packages.

ICs coupled with PCBs generate heat during operation. Too much heat at an IC during operation can damage the IC and/or other electrical components. Traditional lead-frame packages may attach a thermal pad (e.g., die pad) between the bottom surface of the IC and a PCB to dissipate heat. In some embodiments, the PCB may provide further thermal dissipation structures at the intersection of the thermal pad and the PCB, for example, a thermally conductive surface configured to interface with the thermal pad. However, some lead-frame packages, particularly lead-frame packages in high power applications, may require additional heat dissipation methods to dissipate the amount of heat generated by an IC in the lead-frame package during operation.

Some additional examples have utilized a thermally conductive cover attached to the IC with a solder paste. However, such examples may be bulky. In addition, such examples may prevent conductive wire bond pads on the top surface of the IC die, which enable wire bonds to be connected to the top surface of the IC die.

The various example embodiments described herein utilize various techniques to dissipate heat at an IC die in a lead-frame package. For example, in some embodiments, a thermally conductive structure, in thermal contact with the IC die of the lead-frame package, is provided. The thermal conductive structure comprises an anchor portion attached to a surface of the lead-frame package frame portion. The thermal conductive structure further comprises a bridge portion extending from the anchor portion of the thermally conductive structure to a top surface of the IC die. The width of the bridge portion of the thermally conductive structure is less than the width of the top surface of the IC die. Having a bridge width less than the width of the top surface of the IC die enables wire bond connections to be attached at the top surface of the IC die. The bridge portion of the thermally conductive structure is attached to the top surface of the IC die with a thermally conductive but electrically insulating material. Further, in some embodiments, the bridge portion (e.g., elevated portion) of the thermally conductive structure may be exposed at the top package surface of the lead-frame package. Exposing the thermally conductive structure at the top package surface of the lead-frame package may further improve the heat dissipation of the IC die in the lead-frame package.

As a result of the herein described example embodiments and in some examples, the heat dissipation of an IC die in a lead-frame package may be greatly improved. In addition, a thermally conductive structure in accordance with the present disclosure may provide greater flexibility in the functionality and structure of an IC die and the corresponding lead-frame package, for example, by enabling use in high power applications and enabling top IC surface wire bond attachments in high power applications. In addition, a thermally conductive structure in accordance with the present disclosure may provide a simple, low-cost, and low area solution to improve heat dissipation in lead-frame packages.

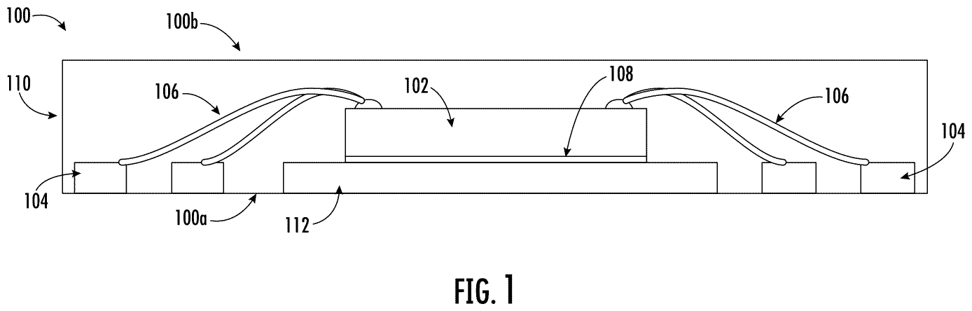

Referring now to FIG. 1, and example lead-frame package 100 is provided. As depicted in FIG. 1, the example lead-frame package 100 includes a frame portion comprising a die pad 112 and a plurality of leads 104. An IC die 102 is attached to the die pad 112 with a die attach substance 108. Bond wires 106 electrically connected the IC die 102 to the leads 104 of the frame portion of the lead-frame package 100. A molding material 110 defines the boundaries of the lead-frame package 100, forming a barrier between at least the IC die 102 and a surrounding environment. The molding material 110 defines a top surface 100b and a bottom surface 100a of the lead-frame package 100. As further depicted in FIG. 1, the frame portion comprising the die pad 112 and the plurality of leads 104 comprise at least a portion of the bottom surface 100a of the lead-frame package 100. As depicted in FIG. 1, the die pad 112 may further be referred to as a bottom exposed die pad 112.

A lead-frame package 100 is any structure for providing an electrical connection to a semiconductor IC without the use of through-holes or exposed wire bonds. A lead-frame package 100 provides a surface-mount and/or socket mount from a semiconductor IC contained within the lead-frame package 100 to an electrical system (e.g., a PCB). Conductive bond wires 106 are contained within the lead-frame package 100 with an electrical connection to the IC die 102 provided through a plurality of leads 104 exposed on the bottom surface 100a of the lead-frame package 100. A lead-frame package 100 provides structural support to an IC die and the conductive bond wires 106. The lead-frame package 100 further protects the electrical components, including the IC die 102, from the environmental factors of a surrounding environment, such as wind, rain, dirt, liquids, extreme temperatures, and so on. Non-limiting examples of lead-frame packages 100 may include quad-flat packages, quad-flat no-leads (QFN) packages, quad-flat no-leads multi-row (QFNmr) packages, dual-flat no-leads (DFN) packages, and so on. Although primarily depicted as a lead-frame package 100 comprising a molding material 110, in some embodiments, the lead-frame package 100 may comprise an air cavity lead-frame package in which the outer boundaries of the lead-frame package 100 are defined by a rigid boundary.

As depicted in FIG. 1, the lead-frame package 100 includes an IC die 102. An IC die 102 (e.g., semiconductor IC) is any block of semiconductor material utilizing circuitry and/or electrical components to perform one or more functions. An IC die 102 may include a processor, a field-programmable gate-array (FPGA), passive electrical components, active electrical components, memory, communications circuitry, and/or any other electrical components necessary to perform the functionality of the IC die 102.

An IC die 102 is further configured to receive and/or generate one or more electrical signals. The one or more electrical signals are transmitted between the IC die 102 and an electrical system through the one or more leads 104. As depicted in FIG. 1, the one or more leads 104 provide an external conductive surface to electrically interface with the IC die 102.

As depicted in FIG. 1, each lead 104 is electrically coupled to the IC die 102 with a conductive bond wire 106. A conductive bond wire 106 is any electrically conductive material forming a conductive path from a lead 104 to an electrical input and/or output of the IC die 102. The conductive bond wire 106 facilitates the transmission of electrical signals between the IC die 102 and the leads 104, providing an electrical connection to an external electrical system. Conductive bond wires 106 may comprise aluminum, copper, silver, gold, or other similar conductive materials. In some embodiments, a conductive bond wire 106 may be attached using a ball bonding technique, or a wedge bonding technique.

As further depicted in FIG. 1, the example lead-frame package 100 includes a frame portion comprising a die pad 112 and a plurality of conductive leads 104. The frame portion of a lead-frame package 100 comprises the conductive base elements of the lead-frame package (e.g., die pad 112 and conductive leads 104). In some embodiments, the frame portion may be manufactured by stamping or chemically etching a flat sheet of conductive material. The frame portion of the lead-frame package 100 forms at least a portion of the bottom surface 100a of the lead-frame package 100.

The die pad 112 comprises any thermally conductive material configured to transfer heat from the lead-frame package 100 to a fluid (e.g., air, liquid coolant) in the surrounding environment and/or to a thermal dissipation region of a mounting surface (e.g., PCB). A die pad 112 may comprise copper, aluminum, aluminum alloys, or other similar thermally conductive material. The material comprising a die pad 112 may depend on the application, heat intensity, production method, budget, and other factors.

As further depicted in FIG. 1, the frame portion of the example lead-frame package 100 includes a plurality of leads 104. Leads 104 are any conductive surfaces configured to provide an electrical connection to a semiconductor IC within a lead-frame package 100. The leads 104 may be electrically coupled to distinct electrical components of the semiconductor IC within the lead-frame package 100. For example, one lead 104 may be electrically coupled to a clock, another may be electrically coupled to a reset signal, a third may be electrically coupled to an output signal of the IC die 102, and so on. The leads 104 may be positioned to align with one or more conductive pads on the mounting surface of an electrical system (e.g., a PCB). The leads 104 may enable a lead-frame package 100 to be electrically coupled to an electrical system utilizing surface-mount technologies, socket-mount technologies, or other similar mount technologies. In some embodiments, the lead-frame package 100 may include multiple rows of leads 104 increasing the number of electrical connections between a semiconductor IC and the electrical system.

As further depicted in FIG. 1, an IC die 102 is attached to the thermal die pad 112 using a die attach substance 108. A die attach substance 108 is any bonding substance configured to attach the IC die 102 to a frame portion (e.g., die pad 112) of the lead-frame package 100. The IC die 102 may be attached to the frame portion by means of a substance, such as, solder paste, die attach film, glue, etc. In some embodiments, the die attach substance 108 may comprise a thermally conductive substance enabling a thermally conductive interface between the IC die 102 and the die pad 112. Such an embodiment enables the transfer of heat from the IC die 102 and to a thermal die pad, for example on an underlying PCB.

Although not depicted in FIG. 1, in some embodiments, the lead-frame package 100 may be coupled to a PCB. A PCB is a structure comprising laminated layers of conductive and insulating material, providing rigid structure and electrical connections between various electrical components (e.g., lead-frame packages 100) of a circuit.

As further depicted in FIG. 1, the example lead-frame package 100 includes a molding material 110. The molding material 110 comprises any non-conductive material configured to protect an IC die 102 within the lead-frame package 100 from a surrounding environment. For example, in some embodiments, an IC die 102 may be on an electrical system in a harsh environment (e.g., high temperatures, low temperatures, exposed to dirt, water, dust, sand, etc.). For example, a lead-frame package 100 may be utilized to protect an IC die 102 in a portion of an automobile (e.g., engine, chassis, driveline, etc.). As depicted in FIG. 1, the molding material 110 is formed to define a bottom surface 100a and a top surface 100b of the lead-frame package 100. The molding material 110 may comprise a resin, polymer plastic, or other insulating material.

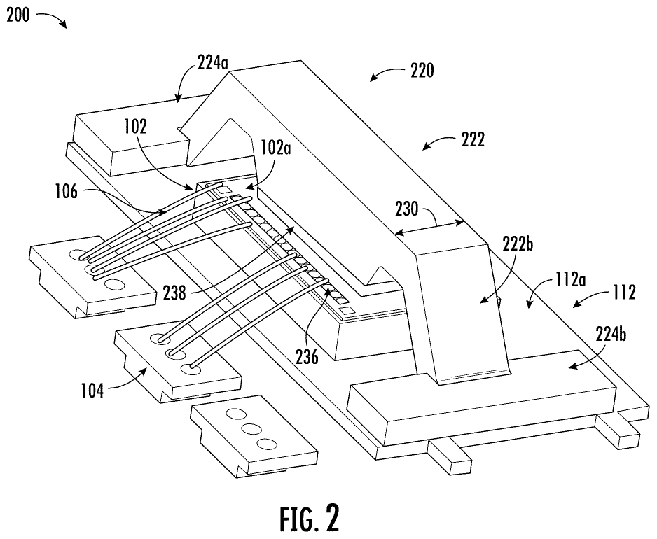

Referring now to FIG. 2, an example thermally conductive structure 220 within a lead-frame package 200 is provided. As depicted in FIG. 2, the example lead-frame package 200 comprises an IC die 102 attached to a top surface 112a (e.g., top frame surface) of a die pad 112 (e.g., frame portion) of the lead-frame package 200. The IC die 102 comprises a top surface 102a (e.g., top IC surface) comprising a plurality of wire bond pads 236. The plurality of wire bond pads 236 provide a plurality of electrical connections to the IC die 102. Thus, electrical connections between the IC die 102 and the external electronic system are formed by attaching bond wires 106 between the wire bond pads 236 and the leads 104.

As further depicted in FIG. 2, the example thermally conductive structure 220 comprises a first anchor portion (e.g., cross member 224a) attached to the top surface 112a of the die pad 112 (e.g., frame portion) at a first end of the IC die 102, and a second anchor portion (e.g., cross member 224b) attached to the top surface 112a of the die pad 112 (e.g., frame portion) at a second end of the IC die 102. An anchor portion of a thermally conductive structure 220 is any portion of the thermally conductive structure 220 which is attached to any surface of the frame portion (e.g., IC die pad 112, lead 104) of the lead-frame package 200. The anchor portion of the thermally conductive structure 220 provides a thermal dissipation path between the bridge portion 222 of the thermally conductive structure 220 and the die pad 112 (e.g., frame portion) of the lead-frame package 200. In addition, by attaching to the die pad 112, the anchor portion stabilizes the thermally conductive structure 220 against the top surface 102a of the IC die 102. In some embodiments, the anchor portions of the thermally conductive structure 220 may be attached to the die pad 112 with a thermally conductive and non-insulating adhesive substance. The anchor portion is further associated with an anchor portion height. The anchor portion height 234 is the height of the anchor portion above the top surface 112a of the die pad.

As depicted in FIG. 2, the cross members 224a, 224b comprise anchor portions of the thermally conductive structure 220. As further depicted in FIG. 2, the thermally conductive structure 220 comprises a bridge portion 222. The bridge portion 222 of the thermally conductive structure 220 crosses over the IC die 102 and attaches to the first cross member 224a and the second cross member 224b at either end of the IC die 102. The bridge portion 222 is thermally connected to the top surface 102a of the IC die 102 with a thermally conductive and electrically insulating IC attach material 238. Thus, heat generated by the IC die 102 is transmitted through the IC attach material 238 into the thermally conductive structure 220. Heat transmitted into the thermally conductive structure 220 may be dissipated across the surface area of the thermally conductive structure 220. In addition, heat may be transmitted into the frame portion (e.g., IC die pad 112) of the lead-frame package 200 and may be further dissipated through the IC die pad 112.

An IC attach material 238 may comprise any thermally conductive and electrically insulating material. In some embodiments, the IC attach material 238 may comprise an adhesive to further attach the thermally conductive structure 220 to the top surface 102a of the IC die 102. For example, the IC attach material 238 may comprise any adhesive comprising non-conductive fillers such as silica, alumina, aluminum hydroxide, mica, and glass. Such fillers may also be employed for their thermally conductive properties, making such fillers ideal for bonding heat-dissipating components to heat sinks.

As further depicted in FIG. 2, the bridge portion 222 of the thermally conductive structure 220 comprises a uniform bridge portion width 230. The bridge portion width 230 indicates the distance from one side of the bridge portion 222 of the thermally conductive structure 220 to the opposite side, perpendicular to the path of the bridge portion 222 from the top surface 102a of the IC die 102 to the anchor portion of the thermally conductive structure 220 (e.g., bridge portion length). As depicted in FIG. 2, the bridge portion width 230 is uniform across the length of the bridge portion 222. In addition, the bridge portion width 230 is less than the width of the underlying IC die 102. With the bridge portion width 230 less than the width of the underlying IC die 102, the thermally conductive structure 220 may be configured to be positioned in thermal contact with the IC die 102 while still enabling one or more wire bond pads 236 on the top surface 102a of the IC die 102.

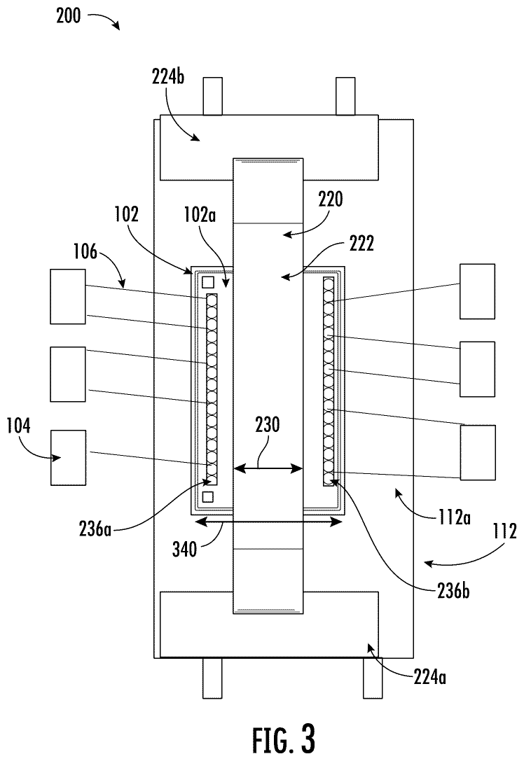

Referring now to FIG. 3, an overhead view of the example thermally conductive structure 220 within the lead-frame package 200 is provided. As depicted in FIG. 3, the thermally conductive structure 220 comprises a first cross member 224a and a second cross member 224b (e.g., anchor portions) attached to a top surface 112a of the IC die pad 112. The thermally conductive structure 220 further includes a bridge portion 222 comprising a uniform bridge portion width 230 attached between the first cross member 224a and the second cross member 224b. The bridge portion 222 is thermally attached to the top surface 102a of the IC die 102. The IC die 102 is further attached to the top surface 112a (e.g., top frame surface) of the die pad 112 (e.g., frame portion).

As depicted in FIG. 3, the IC die 102 comprises an IC die width 340. In addition, the top surface 102a of the IC die 102 comprises a first set of wire bond pads 236a on a first side of the top surface 102a and a second set of wire bond pads 236b on a second side of the top surface 102a. One or more of the wire bond pads may be electrically connected to one or more of the leads 104 by a bond wire 106.

As depicted in FIG. 3, the IC die width 340 indicates a lateral distance from the first side of the top surface 102a of the IC die 102 to the second side of the top surface 102a of the IC die 102. As depicted, the IC die width 340 is greater than the bridge portion width 230 of the bridge portion 222 of the thermally conductive structure 220. Indeed, the bridge portion 222 of the thermally conductive structure 220 is attached to the top surface 102a of the IC die 102 between the first set of wire bond pads 236a and the second set of wire bond pads 236b.

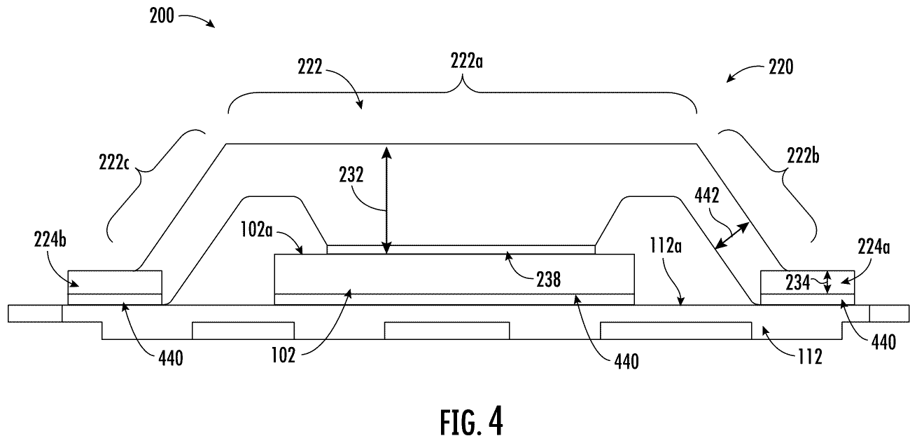

Referring now to FIG. 4, a side view of a lateral cross section of the example thermally conductive structure 220 within the lead-frame package 200 is provided. As depicted in FIG. 4, the thermally conductive structure 220 comprises a first cross member 224a and a second cross member 224b (e.g., anchor portions) attached to a top surface 112a of the IC die pad 112 with an adhesive 440. The thermally conductive structure 220 further includes a bridge portion 222 attached between the first cross member 224a and the second cross member 224b. The bridge portion 222 is further thermally attached to the top surface 102a of the IC die 102 with an IC attach material 238. The IC die 102 is further attached to the top surface 112a (e.g., top frame surface) of the die pad 112 (e.g., frame portion) with an adhesive 440.

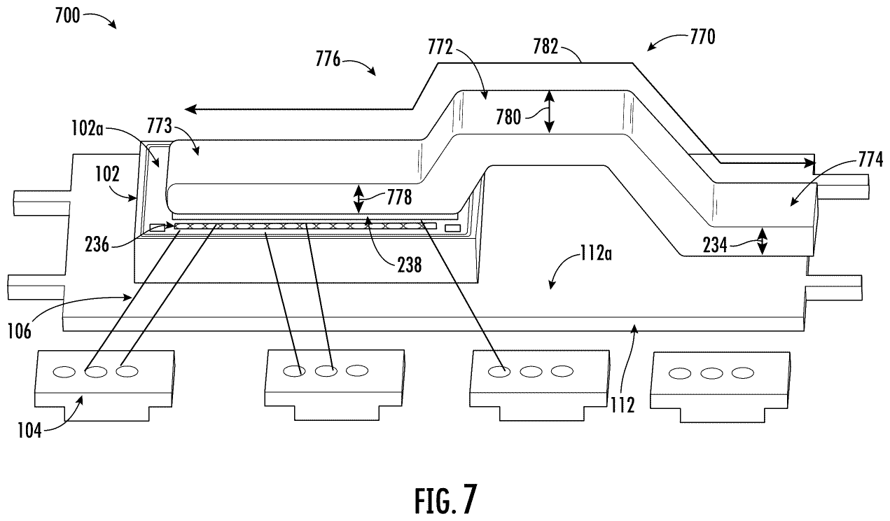

As further depicted in FIG. 4, the bridge portion 222 comprises a first sub portion 222a (e.g., elevated portion) associated with a first height 232, a second sub portion 222b associated with a second height 442, and a third sub portion 222c. Although the first height 232 and the second height 442 as depicted in FIG. 4 are different, in some embodiments, the first height 232 and the second height 442 may be the same. For example, as further described in relation to FIG. 7.

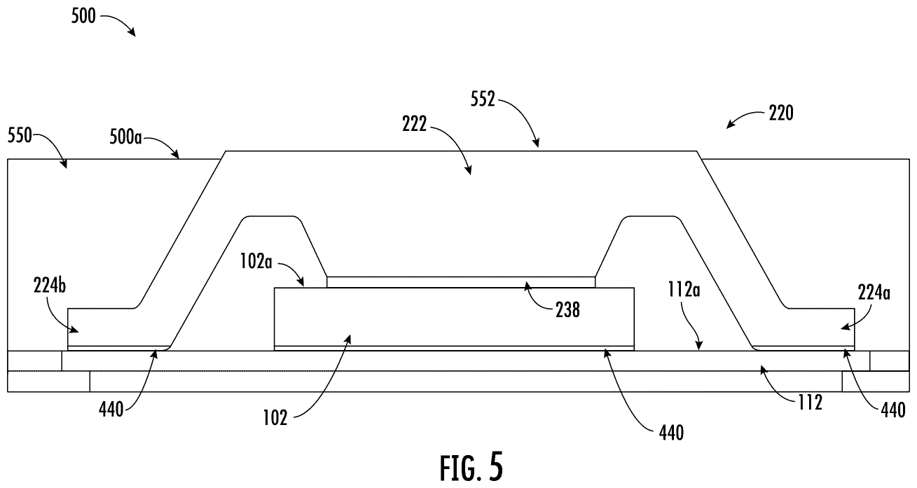

The first sub portion 222a is configured to thermally attach to the top surface 102a of the IC die 102. The second sub portion 222b and third sub portion 222c comprise the bridge portion 222 between the first sub portion 222 a and the respective cross members 224a/224b. As depicted in FIG. 4, the first height 232 represents the distance from the bottom surface of the first sub portion 222a, adjacent the top surface 102a of the IC die 102, to the top surface of the first sub portion 222a. In some embodiments, the first height 232 at the first sub portion 222a may be increased relative to the second height 442 at the second sub portion 222b and the third sub portion 222c. Increasing the first height 232 at the first sub portion 222a may enable the bridge portion 222 of the thermally conductive structure 220 to maintain thermal contact with the top surface 102a of the IC die 102 and be exposed to an environment external to the lead-frame package 200 (as described in relation to FIG. 5). In some embodiments, the first sub portion 222a of the bridge portion 222 may be referred to as the elevated portion.

As further depicted in FIG. 4, the anchor portions may be associated with an anchor portion height 234. The anchor portion height corresponds to the distance from the bottom surface of the anchor portion of the thermally conductive structure 220, adjacent to the top surface 112a of the IC die pad 112, to the top surface of the anchor portion. As depicted in FIG. 4, the anchor portion height 234 is less than the first height 232.

As further depicted in FIG. 4, the cross members 224a, 224b and the IC die 102 are attached to the top surface 112a of the IC die pad 112 with an adhesive 440. The adhesive 440 comprises any substance or material, such as glue, solder paste, or die attach film (DAF), configured to adhere the IC die 102 and cross members 224a, 224b to the top surface 112a of the IC die pad 112. In some embodiments, other mechanisms may be used to attach the cross members 224a, 224b and the IC die 102 to the top surface 112a of the IC die pad 112. For example, mechanical mechanisms such as screws and/or latches.

Referring now to FIG. 5, a side view of a cross section of the example thermally conductive structure 220 within a lead-frame package 500 comprising a molding material 550 is provided. As depicted in FIG. 5, the thermally conductive structure 220 comprises a first cross member 224a and a second cross member 224b (e.g., anchor portions) attached to a top surface 112a of the IC die pad 112. The thermally conductive structure 220 further includes a bridge portion 222 attached between the first cross member 224a and the second cross member 224b. The bridge portion 222 is further thermally attached to the top surface 102a of the IC die 102 with an IC attach material 238. The IC die 102 is further attached to the top surface 112a (e.g., top frame surface) of the die pad 112 (e.g., frame portion) with an adhesive 440.

As depicted in FIG. 5, cross section view cuts along the lateral length of the bridge portion 222 of the thermally conductive structure 220, the, the leads (e.g., leads 104) at the external edges of the lead-frame package 500 are no longer visible. Instead, the exposed IC die pad 112 and bottom side of the lead-frame are shown.

As further depicted in FIG. 5, a molding material 550 is utilized to protect the components of the lead-frame package 500 and define the outer dimensions of the lead-frame package 500, including the top package surface 500a of the lead-frame package 500. As shown in FIG. 5, the top surface 552 (e.g., elevated portion) of the bridge portion 222 of the thermally conductive structure 220 is exposed at the top package surface 500a of the lead-frame package 500. Exposing the thermally conductive bridge portion 222 of the thermally conductive structure 220 at the top package surface 500a of the lead-frame package 500 may further improve heat dissipation from the IC die 102. For example, exposing the bridge portion 222 to an external environment may enable the transfer of heat from the lead-frame package 500 to a fluid (e.g., air, liquid coolant) in the surrounding environment.

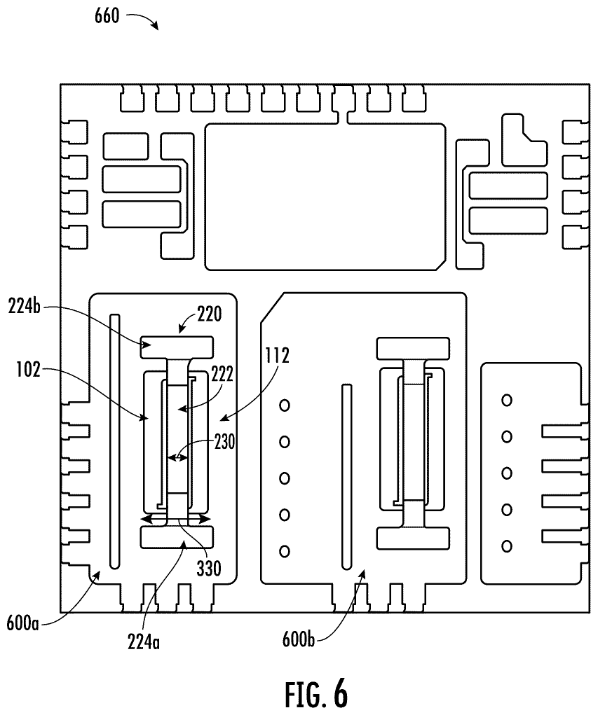

Referring now to FIG. 6, an example electronic system 660 comprising a plurality of surface mounted lead-frame packages 600a, 600b attached to a system interconnection board 662 (e.g., PCB) is provided. As depicted in the example lead-frame package 600a of FIG. 6, an IC die 102 is attached to a die pad 112. In addition, a thermally conductive structure 220 comprising a bridge portion 222, a first cross member 224a, and a second cross member 224b. The bridge portion 222 of the thermally conductive structure 220 is thermally attached to a top surface of the IC die 102 with an IC thermal attach material. As further depicted in FIG. 6, the bridge portion width 230 of the thermally conductive structure 220 is less than the IC die width 330, such that the bridge portion 222 may be attached to the top surface of the IC die 102 between any wire bond pads on the top surface of the IC die 102. Utilizing the heat dissipation techniques described herein in electronic systems, such as the electronic system 660 displayed in FIG. 6 may enable greater flexibility in the design and operation of electronic systems 660. For example, the improved heat dissipation may enable use of the lead-frame packages in high power applications. In addition, the complexity, area, and cost of lead-frame packages operating in high power applications may be reduced. Thus, enabling use of the lead-frame package in certain high power consumer applications. Some such applications may include AC/DC conversion circuits, motor controllers, and the like.

Referring now to FIG. 7, a perspective view of an example embodiment of a thermally conductive structure 770 within a lead-frame package 700 is provided. As depicted in FIG. 7, the thermally conductive structure 770 comprises an anchor portion 774 attached to a top surface 112a of the IC die pad 112. The thermally conductive structure 770 further includes a bridge portion 776 extending from the anchor portion 774 to the top surface 102a of the IC die 102. A plurality of wire bond pads 236 are positioned on one or more sides of the top surface 102a of the IC die 102. The wire bond pads 236 may be electrically connected to one or more leads 104 by a bond wire 106. The bridge portion 776 is attached to the top surface 102a of the IC die 102 adjacent to the wire bond pads 236 with an IC attach material 238. The bridge portion 776 further comprises an elevated portion 772. As further depicted in FIG. 7, the IC die 102 is attached to the top surface 112a (e.g., top frame surface) of the die pad 112 (e.g., frame portion).

As depicted in FIG. 7, the example thermally conductive structure 770 comprises a uniform structure height 778. As used herein, a uniform structure height 778 indicates the height of the thermally conductive structure 770 is uniform or nearly uniform across the entire structure length 782 of the thermally conductive structure 770. In some embodiments, a uniform structure height 778 may simplify the manufacturing process while still providing improved heat dissipation from the IC die 102. In such an embodiment, the anchor portion height is equivalent to the bridge portion height.

As further depicted in FIG. 7, the thermally conductive structure 770 comprises a uniform structure width 780. As used herein, a uniform structure width 780 indicates the width of the thermally conductive structure 770 is uniform or nearly uniform across the entire structure length 782 of the thermally conductive structure 770.

As further depicted in FIG. 7, the bridge portion 776 of the thermally conductive structure 770 comprises an attached portion 773. The attached portion 773 is attached to the top surface 102a of the IC die 102 with an IC attach material 238. An attached portion 773 may be attached to the top surface 102a of the IC die 102 using a thermally conductive but electrically insulating IC attach material 238. For example, a thermally conductive but electrically insulating glue. The thermally conductive glue enables heat dissipation to occur through the thermally conductive structure 770 and the IC die pad 112. As depicted in FIG. 7, the uniform structure width 780 of the attached portion 773 enables the attached portion 773 to attach to the top surface 102a of the IC die 102 between any wire bond pads 236, preventing disruption to the electrical connections formed at the wire bond pads 236. In addition, utilizing a non-electrically conductive IC attach material 238, such as a glue, prevents shorting any of the electrical connections on the top surface 102a of the IC die 102.

As further depicted in FIG. 7, the bridge portion 776 of the thermally conductive structure 770 comprises an elevated portion 772. The elevated portion 772 of the bridge portion 776 comprises any portion of the thermally conductive structure 770 between the anchor portion 774 and the attached portion 773, extending above the attached portion 773. In some embodiments, the elevated portion 772 may be exposed at a top package surface of the lead-frame package 700. For example, the elevated portion 772 may be exposed after a molding material is applied to the lead-frame package 700. Exposing the elevated portion 772 at the top package surface of the lead-frame package 700 may further improve heat dissipation from the IC die 102.

Although not depicted in FIG. 7, in some embodiments, the anchor portion 774 may further comprise a cross member, for example cross member 224a, 224b as described in relation to FIG. 2-FIG. 6. A cross member may be integrated with the anchor portion 774 and positioned perpendicular to the elevated portion 772 of the thermally conductive structure 770. A cross member may further attach to the top surface 112a of the IC die pad 112, for example, with an adhesive.

While this detailed description has set forth some embodiments of the present invention, the appended claims cover other embodiments of the present invention which differ from the described embodiments according to various modifications and improvements. For example, one skilled in the art may recognize that such principles may be applied to any electronic device comprising a limited surface area from which heat may be dissipated. For example, any electrical component with electrical connections on or near every surface of the electrical component.

Within the appended claims, unless the specific term “means for” or “step for” is used within a given claim, it is not intended that the claim be interpreted under 35 U.S.C. 112, paragraph 6.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

1. A lead-frame package comprising:
a frame portion;
an integrated circuit die comprising an integrated circuit die width, wherein the integrated circuit die is positioned on the frame portion;
a thermally conductive structure, the thermally conductive structure comprising:
an anchor portion, wherein the anchor portion is attached to a top frame surface of the frame portion; and
a bridge portion comprising a uniform bridge portion width,
wherein the uniform bridge portion width is less than the integrated circuit die width, and
wherein the bridge portion is in thermal contact with the integrated circuit die.

2. The lead-frame package of claim 1, the integrated circuit die comprising a first set of wire bond pads on a first side of a top IC surface, and a second set of wire bond pads on a second side of the top IC surface.

3. The lead-frame package of claim 2, wherein the bridge portion of the thermally conductive structure is attached to the top IC surface between the first set of wire bond pads and the second set of wire bond pads.

4. The lead-frame package of claim 1, wherein the thermally conductive structure is attached to the integrated circuit die with an IC attach material, wherein the IC attach material is a thermally conductive but electrically insulating material.

5. The lead-frame package of claim 1, wherein a molding material defines a top package surface of the lead-frame package, and wherein an elevated portion of the bridge portion of the thermally conductive structure is exposed at the top package surface.

6. The lead-frame package of claim 1, wherein a structure height associated with the thermally conductive structure is uniform along a structure length of the thermally conductive structure.

7. The lead-frame package of claim 1, the thermally conductive structure further comprising:
a first end of the bridge portion,
wherein a first cross member is attached to the first end of the bridge portion, and
the first cross member is attached to the frame portion of the lead-frame package.

8. The lead-frame package of claim 7, the thermally conductive structure further comprising:
a second end of the bridge portion;
wherein a second cross member is attached to the second end of the bridge portion, and
the second cross member is attached to the frame portion of the lead-frame package.

9. The lead-frame package of claim 8, wherein the bridge portion comprises:
a first sub portion comprising a first height, wherein the first sub portion is in thermal contact with the integrated circuit die; and
a second sub portion comprising a second height, wherein the second height is less than the first height.

10. The lead-frame package of claim 9, wherein the first height associated with the first sub portion of the bridge portion is greater than an anchor portion height associated with the anchor portion.

11. A thermally conductive structure configured to dissipate heat at an integrated circuit die, the thermally conductive structure comprising:
an anchor portion, wherein the anchor portion is attached to a top frame surface of a frame portion of a lead-frame package; and
a bridge portion comprising a uniform bridge portion width,
wherein the uniform bridge portion width is less than an integrated circuit die width associated with the integrated circuit die of the lead-frame package, and
wherein the bridge portion is in thermal contact with the integrated circuit die.

12. The thermally conductive structure of claim 11, wherein the integrated circuit die comprises a top IC surface, and wherein the bridge portion of the thermally conductive structure is attached to the top IC surface between a first set of wire bond pads and a second set of wire bond pads.

13. The thermally conductive structure of claim 11, wherein the thermally conductive structure is attached to the integrated circuit die with an IC attach material, wherein the IC attach material is a thermally conductive but electrically insulating material.

14. The thermally conductive structure of claim 11, wherein an elevated portion of the bridge portion is exposed at a top package surface of the lead-frame package.

15. The thermally conductive structure of claim 11, further comprising a structure height, wherein the structure height is uniform along a structure length of the thermally conductive structure.

16. The thermally conductive structure of claim 11, further comprising:
a first end of the bridge portion,
wherein a first cross member is attached to the first end of the bridge portion, and
the first cross member is attached to the frame portion of the lead-frame package.

17. The thermally conductive structure of claim 16, further comprising:
a second end of the bridge portion;
wherein a second cross member is attached to the second end of the bridge portion, and
the second cross member is attached to the frame portion of the lead-frame package.

18. The thermally conductive structure of claim 17, wherein the bridge portion comprises:
a first sub portion comprising a first height, wherein the first sub portion is in thermal contact with the integrated circuit die; and
a second sub portion comprising a second height, wherein the second height is less than the first height.
